(19) United States
(12) Patent Application Publication
(10) Pub. No.: US 2009/0020215 A1
(43) Pub. Date: Jan. 22, 2009

(54) Optical Coatings With Narrow Conductive Lines

(76) Inventors: Thomas G. Hood, Portola Valley, CA (US); Sicco W. T. Westra, Los Altos Hills, CA (US)

Correspondence Address: SCHNECK & SCHNECK, P.O. BOX 2-E, SAN JOSE, CA, 95109-0005, US

(21) Appl. No.: 11/918,338

(22) PCT Filed: Apr. 14, 2006
(86) PCT No.: PCT/US2006/013993

§ 371 Date: Oct. 11, 2007

Related U.S. Application Data
(60) Provisional application No. 60/671,804, filed on Apr. 15, 2005.

(51) Int. Cl. B32B 38/14; H05K 3/10; C25D 5/02; C25D 5/34

(52) U.S. Cl. 156/151; 205/125; 205/91; 427/98.4; 427/97.3

(57) ABSTRACT

Conductive micro traces (64) are formed on a coated or uncoated substrate (28) in order to achieve a combination of target optical properties and target electrical capabilities. For the coated substrate, the coating (100) may be formed before or after the conductive micro traces. The coating may be designed for providing IR filtering or reductions in reflected light and color shift, while the conductive micro traces may be used for EMI shielding or to provide current-carrying capability, such as when used as heaters. In another embodiment, the conductive micro traces are formed on an uncoated flexible transparent substrate and have a width of less than 25 microns, such that the conductive micro traces are capable of achieving their intended purpose while maintaining a high visible light transmissivity. The conductive micro traces may be formed using various approaches, such as the use of electroplating techniques or the use of inkjet printing techniques.

### TECHNICAL FIELD

The invention relates generally to optical filters and more particularly to filters applied to viewing surfaces, including plasma display panels and glass used for vehicles, buildings, refrigeration and the like.

### BACKGROUND ART

The selection of target optical properties for coatings on a substrate will vary significantly, depending upon the intended application. For example, U.S. Pat. No. 5,071,206 to Hood et al., which is assigned to the assignee of the present patent document, describes a filter arrangement which may be used for a vehicle, housing and office windows. For a vehicle window, the number of considerations is increased if the window is to include conductive traces or wiring intended to provide defogging. In comparison, there may be other factors that must be considered in the design of an optical filter for a plasma display panel (PDP). Such factors include the degree of neutrality of transmitted color, the level of reflected light and the color shift with changes in the incidence angle of a viewer, and the transmission levels of infrared and electromagnetic radiation. Unfortunately, modifying a PDP filter to increase conditions with respect to one factor sometimes conflicts with maintaining a target level for another factor. The possibility of tradeoffs is also a concern with other optical members, such as windows for which surface heating is a consideration (e.g., controlled window defogging and deicing).

FIG. 1 is one possible arrangement of layers to provide a filter for a plasma display panel, which includes a module or separate glass sheet 10. The Etalon filter 12 is first formed on a polyethylene terephthalate (PET) substrate 14 that is then affixed to the glass sheet by a layer of adhesive 16. Because a plasma display generates infrared radiation and electromagnetic interference (EMI) that must be controlled in accordance with legislated regulations, the filter layers 12 are designed to reduce infrared and EMI from the display. Etalon filters based on multiple silver layers are used to screen infrared wavelengths and electromagnetic waves. Interference between adjacent silver layers can be tuned to cause resonant transmission in the visible region, while providing desirable screening. The above-cited patent to Hood et al. describes a suitable sequence of layers.

FIG. 1 also includes an antireflection (AR) layer stack 18 that was originally formed on a second PET substrate 20. Antireflection layer stacks are well known in the art. A second adhesive layer 22 secures the PET substrate 20 to the other elements of FIG. 1.

While the PDP filter 12 reduces infrared transmission and EMI from the display, the filter must also be cosmetically acceptable and must enable good fidelity in the viewing of displayed images. Thus, the transmissivity of the filter should be high in the visual region of the light spectrum and should be relatively colorless, so as not to change the color rendering of the plasma display. Further, a general expectation exists that displays should be low in reflectance.

Color can be expressed in a variety of fashions. In the above-cited Hood et al. patent, color is expressed in the CIE La*b*1976 color coordinate system and in particular the ASTM 308-85 method. Using this method, a property is shown by values for a* and b* near 0. Generally, consumers expect that computer displays will appear either neutral or slightly bluish in color. Referring briefly to the La*b* coordinate system shown in FIG. 2, this generally yields the expectation that reflected a* (i.e., Ra*) lies in the range of −2 to approximately 10, and reflected b* (i.e., Rb*) lies in the range −40 to approximately 2. This expectation is shown by dashed lines 23.

Users of large information displays generally expect minimal change in reflected color with changes in the viewing angle. Any color change is distracting when a display is viewed from a close distance, where the color of the display appears to change across the surface. Since plasma display panels are intrinsically large, due to the large number of pixels required for imaging and the large pixel size, the need for reduced color travel with viewing angle is heightened. In particular, it is objectionable if the “red-green” component of color, Ra*, changes substantially with angle. Changes along the other axis, Rb*, are generally less of an issue when the display has large reflected negative Rb* (i.e., strong blue reflected color) at normal incidence.

As previously noted, different factors regarding the design of PDP filters may conflict. Generally, obtaining high visible transmission and infrared reflection competes with EM screening capability.

Controlling reflection within the red region of the light spectrum is rendered even more difficult by the need for a low sheet resistance in the PDP filter 12. Attempts have been made to balance the goals of maximizing red transmission and minimizing sheet resistance. U.S. Pat. No. 6,102,530 to Okamura et al. describes an optical filter for plasma displays, where the filter has a sheet resistance of less than 3 ohms/square. Generally, a sheet resistance of less than 1.0 ohms/square is required to meet Federal Communication Commission (FCC) Class B standard, even for PDP sets having the highest luminance efficiencies. Copper wire mesh PDP EMI filters having a sheet resistance of 0.1 to 0.2 ohms/square are often used to provide Class B compatibility.

The requirement for lower sheet resistance increases the color problem for etalon EMI filters. The transmission bandwidth of the filter becomes narrower as the conductive layers become thicker, resulting in both an increase in the red reflection and a loss of color bandwidth in transmission.

FIG. 2 illustrates the difficulty with a four silver layer coating designed for a PDP. The plot 24 shows color as a function of viewing angle from normal incidence to 60 degrees. The four silver layer coating may have an acceptable sheet resistance and may have a total silver thickness of 45 nm to provide an acceptable color appearance at normal incidence. However, as the illustration shows, when the coating is viewed at 60 degrees, the reflected light is strongly red, with Ra* of approximately 30. In addition, there is a large color shift with incidence angle, which creates an apparent color difference across the screen for a large screen viewed at a close distance. Thus, despite the suitability of the coating for some Class B EMI applications, this coating may be considered cosmetically unacceptable.

The use of thin silver layers in multilayered sputtered coatings gives the conductive properties to these products. However, certain applications require electrical properties that are beyond the physical/optical and/or economic capabilities of sputtered films alone. The increased electrical conductivity in sputtered thin film products can be accomplished, generally, through the use of thicker silver layers, and/or the use of a greater number of silver layers of a given thickness. Both of these methods contribute to lower visible light transmission and/or higher visible light reflection, and thus create unacceptable optics for the application. The general limitations of these silver-dielectric coatings for optical applications (visible light transmission >˜50%) are with sheet resistances in the range of ˜1-7 ohms/square, whereas the preferred electrical resistance for certain key markets (such as plasma EMI display filters and heated automotive glass) is in the 0.7 ohm/square range, or lower. In the automotive applications, the available electrical potential is relatively low (14 volts), so sheet resistance is a concern if the glass is to be heated efficiently. The need to increase electrical conductivity without negatively affecting the optical properties is essential. It is also important that the desired electro-optical properties are obtained in a cost-effective way.

What is needed is a filter that addresses the issues regarding emission control, color travel, color bandwidth, and low sheet resistance in transmission for use with a viewing surface, such as a plasma display screen or a window of a vehicle.

### SUMMARY OF THE INVENTION

It is often desirable either for the protection or convenience of a user to provide a substrate having a target combination of optical and electrical properties. In some applications, the desired optical properties may merely be maintaining sufficient transparency while achieving the target electrical properties. For these applications, the invention described below may be applied to an uncoated flexible substrate. In other applications, the goal may be to obtain more sophisticated optical filtering capabilities, such as IR filtering or reductions in reflected light and color shift, in combination with achieving electrical properties, such as heating or EMI shielding. In these applications, the invention is applied to a substrate which has an optical coating or to a substrate to which an optical coating is subsequently formed.

Coatings which are comprised of a sequence of layers that are cooperative to provide filtering properties are known. However, the known techniques may not provide a sufficiently low sheet resistance or may not provide desired heating capability. Therefore, the invention includes the formation of ultra-narrow conductive traces (conductive micro traces) that are in electrical contact (not necessarily physical contact) with the substrate. These ultra-narrow conductive traces may be used to provide improved conductivity (i.e., lower sheet resistance) over the surface of the substrate. Alternatively, the ultra-narrow conductive traces may be used as current-carrying elements.

One possible embodiment of the invention utilizes metallic inks to form the ultra-narrow conductive traces. The metallic ink may be applied to an inkjet printing process in the form of lines that are deposited at high speeds, preferably in a continuous or semi-continuous method.

A second embodiment of the invention utilizes a photolithographic process. The ultra-narrow metal traces are formed in a multi step that includes dipping the surface upon which the traces are to be printed in a liquid precursor containing a nano-particle catalyst, activating the areas that will form the ultra-narrow metal traces by exposure to UV light, and dipping the exposed surface in a solution containing the metal ions that will grow in the exposed areas. Alternatively, it is possible to use an inverse exposure step and final dipping step. That is, the areas that will not form the traces are exposed to the UV light such that when the surface is dipped into the metal ion solution, the traces will grow in the unexposed areas to form the ultra-narrow conductive traces. Moreover, other approaches to providing ultra-narrow metal traces on a substrate that is then dipped into a solution that includes ions of a highly conductive material (such as silver or copper) may be used. Both sides of the substrate may be immersed in a manner consistent with conventional electroplating or only the side of the substrate on which the ions are to be attacked can be immersed.

A third embodiment of the invention is to provide printing of the ultra-narrow traces using offset, gravure, or a similar type of printing technique in a continuous or semi-continuous mode.

The substrate may be a coated or uncoated plastic or may be glass, either flexible, rigid, flat or bent (such as a shaped automotive windshield). The coating and the ultra-narrow conductive traces may be applied directly to the end product or may be formed on a substrate (e.g., PET) that is to be applied to the final product. Thus, the applications include, but are not limited to, building retrofits, refrigeration glass, vehicle windows for which heating is desired, and plasma display panels. However, the invention is particularly suitable for use in forming vehicle windows and plasma display panels.

As one possibility, the ultra-narrow conductive traces may be formed on a side of the coating opposite to the substrate on which the coating is formed. As a second possibility, the ultra-narrow conductive traces may be formed between the substrate and the coating. It is also possible to form the coating and the ultra-narrow conductive traces on opposite sides of the substrate, if the coating and traces are electrically connected. For example, the traces may be interconnected to a bus which is electrically linked to the coating.

### BRIEF DESCRIPTION OF THE DRAWINGS

FIG. 1 is a cross-sectional view of a filter on a plasma display panel suitable for the present invention.

FIG. 2 is a plot of color as a function of viewing angle for a layer stack having four silver layers in accordance with the prior art.

FIG. 3 is a cross-sectional view of a plasma display filter having a sequence of dielectric and metallic layers in accordance with an embodiment of the present invention.

FIG. 4 is a top view of a filter with ultra-narrow conductive traces.

FIG. 5 is a side cross-sectional view of a portion of the device of FIG. 4.

### DETAILED DESCRIPTION

The object of this invention is to create cost-effective large area devices for applications that require transparent yet electrically conductive properties. Conventional techniques for making transparent dielectric or insulating optical materials/substrates (such as plastic and glass) electrically conductive have optical, electrical, physical and/or economic limitations such that certain product requirements cannot be fully satisfied in many applications.

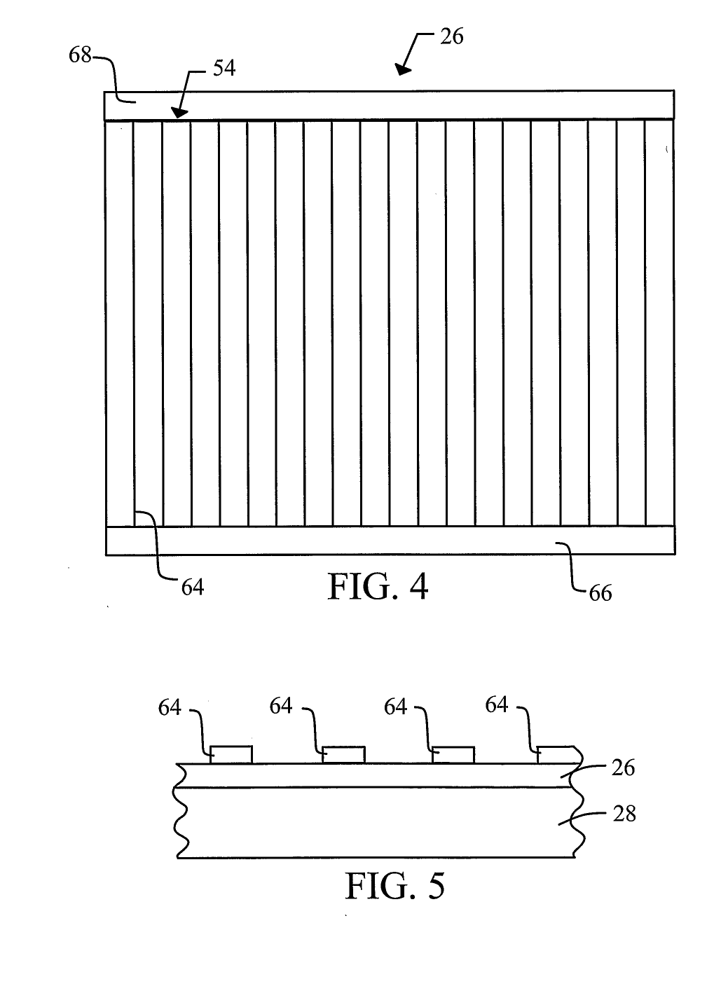

This invention employs highly conductive metal traces 64 (FIGS. 4 and 5), applied in pattern widths less than what is detectable by the human eye (<50 microns, and preferably thinner than 25 microns). Using low-cost printing and/or imaging techniques, the ultra-narrow conductive traces may be applied to products which can meet demanding optical applications while delivering, cost-effectively, low electrical sheet resistance between busbars (which are used for either delivering electrical power, or for grounding in the case of electrical shielding). The combination of these patterned metallic traces with materials that already have low sheet resistance, such as sputtered coatings based on thin silver layers, can create a broad range of materials that can supply multiple functionalities along with electrical conductivity. An example of these functionalities includes the ability to block undesired portions of the electromagnetic spectrum, such as the infrared and ultraviolet portions, while satisfying the electrical conductivity requirements. Such multi-functional products would have great value in architectural, automotive, and electronic display applications.

This invention involves the novel combination of low-cost printing of highly conductive traces in ultra-narrow lines (˜25 microns) over large areas of coated and uncoated substrates (such as plastic and glass) to form multi-functional products useful for a wide range of markets and applications. The improved conductivity (i.e., lower sheet resistance) over the surface of the substrate allows for the use of the material in applications including: active electrical heating, electromagnetic interference shielding, and active transmission/reception of electromagnetic information (antenna) while maintaining high visible light transmission and/or low visible light reflection. For an automobile windshield, the visible light transmissivity must be at least 70 percent in some countries (e.g., vehicles in the United States, as provided by the U.S. National Transportation Safety Board).

One way of applying the narrow conductive metal traces 64 is through the use of metallic inks. The metallic inks contain highly conductive nano-materials (including copper, silver and gold) applied and cured at temperatures low enough for application onto plastic substrates. Furthermore, the application of these inks can be performed by low-cost methods, such as inkjet printing, where the conductive lines are applied at high speeds, potentially in a continuous manner such as on sheets of glass or plastic or roll-to-roll for flexible plastic film. Alternatively, the narrow metal traces can be created through a three-step process of: dipping of the substrate in a liquid precursor, containing nano-particle catalysts (such as palladium), then through selective UV light exposure activate the areas that will form the narrow metal traces (such as a scanning UV laser or exposure through a mask), and finally dipping of the exposed substrate in a solution containing the metal ions that will now selectively grow in the exposed areas, forming the conductive metal trace. Thus, electroplating techniques may be employed. A third embodiment of the invention is to print the ultra-narrow traces using offset, gravure, or similar type printing techniques in a continuous or semi-continuous mode.

The combination of these narrow conductive lines 64 with sputtered coatings creates the ability to meet demanding EMI-shielding applications such as plasma displays, where the required sheet resistance needs to be ˜0.5 ohms/square or less while also meeting the requirement to block the near-IR portion of the spectrum and maintain high visible transmission. Likewise, solar control glass for automobiles uses sputtered coatings to reduce the IR transmission into the vehicle, but for this glass to be actively heated (for defrosting and deicing) with the available 14 volts from the car's battery, the sheet resistance needs to be ˜0.5 ohms/square. The combination of the silver-based sputtered film and the highly conductive metallic ink makes this possible in a cost-effective way.

### EXAMPLE

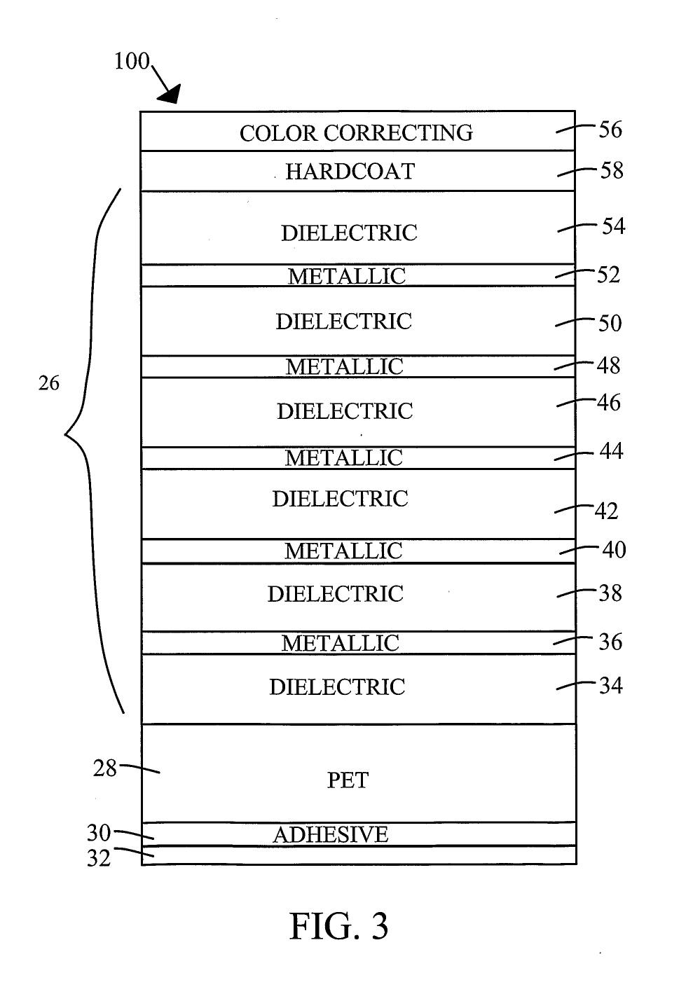

FIG. 3 is included to show one possible sequence of layers with which the invention may be used. With reference to FIG. 3, an alternating pattern 26 of layers is formed on a flexible polymeric substrate 28. The substrate material may be PET having a thickness of 25 to 100 microns. On a side of the substrate opposite to the alternating pattern is a layer of adhesive 30 and a release strip 32. The release strip 32 is easily removed from the adhesive, allowing the adhesive layer to be used to couple the substrate and its layers to a member for which filtering is desired, such as a PDP. In another embodiment, the alternating pattern 26 is formed directly on a plasma display panel, but there are fabrication complication factors which must be addressed in this alternative embodiment. For example, it might be necessary to pass the panel through a sputter chamber for depositing the material which forms the layers.

In forming the alternating pattern 26 of layers, it is desirable to deposit the materials on the polymeric substrate 28 at near room temperature. The alternating pattern includes at least eleven layers, with the layer nearest the substrate being a dielectric layer 34. While not shown in FIG. 3, there may be a primer layer, an adhesion layer or other layers which promote the structural integrity of the filter 100 of FIG. 3. The alternating pattern 26 is formed to maximize the total quantity of silver, while maintaining a bluish reflected color, high transmission, and neutrality of transmission. These properties are obtained with the use of five metallic layers 36, 40, 44, 48 and 52 having a combined thickness greater than 50 nm. The metallic layers may be silver or silver alloy layers. The silver alloy layers may be formed by first sputtering silver and then sputtering a titanium cap layer which is subsequently subjected to alloying and oxidation.

In the fabrication of the filter 100 of FIG. 3, the first dielectric layer 34 may be formed by sputtering dielectric material onto the substrate 28. As previously defined, “dielectric” refers to a high refractive index layer (i.e., a refractive index greater than 1.0). In the preferred embodiment, the refractive index of each dielectric layer 34, 38, 42, 46, 50 and 54 is in the range of 1.8 to 2.5. The thickness of the first dielectric layer is at least 10 nm, with a preferred range of 10 nm to 60 nm. A suitable material is an indium oxide, which may include indium tin oxide. Alternatively, at least one dielectric “layer” of the alternating pattern may be a combination of dielectrics, such as InOₓ and TiOₓ.

Formed atop the first dielectric layer 34 is the first metallic layer 36. A “metallic” layer is a layer having a sufficiently low resistivity to promote an end product having the desired sheet resistance. Each metallic layer may be silver or a silver alloy metal layer. The thickness of the first metallic layer is preferably in the range of 6 nm to 12 nm. A second dielectric/metallic pair in the alternating pattern 26 duplicates the materials of the first pair. The second dielectric layer 38 has a thickness in the range of 70 nm to 95 nm, while the second metallic layer 40 has a thickness in the range of 9 nm to 18 nm. The third and fourth metallic layers 44 and 48 have the same thickness as the second metallic layer 40, within ±20 percent, at least in the preferred embodiment. The thickness of the third, fourth and fifth dielectric layers 42, 46 and 50 is preferably the same as the range of the second dielectric layer 38.

The final metallic layer 52 may be thinner than the middle metallic layers 40, 44 and 48. The thickness of the fifth metallic layer 52 is preferably in the range of 6 nm to 12 nm. Similarly, the final dielectric layer 54 has a reduced thickness, similar to the first dielectric layer 34. The first and sixth dielectric layers 34 and 54 may have a thickness in the range of 20 nm to 60 nm. The various layer thicknesses of the filter 100 can be adjusted within suitable ranges in order to achieve target optical properties for a particular application. If the dielectric layers are equal in thickness and the metallic layers are equal in thickness, a high transparency will result, but with a possible excessive color shift. Therefore, a color correcting layer 56 may be included to provide a color shift that is in the opposite direction, so as to offset the color shift exhibited by the alternating pattern 26. It has been determined that if fewer than five silver alloy layers are used, it is difficult to provide a sheet resistance below 1.2 ohms/square with low color shift with viewing angle.

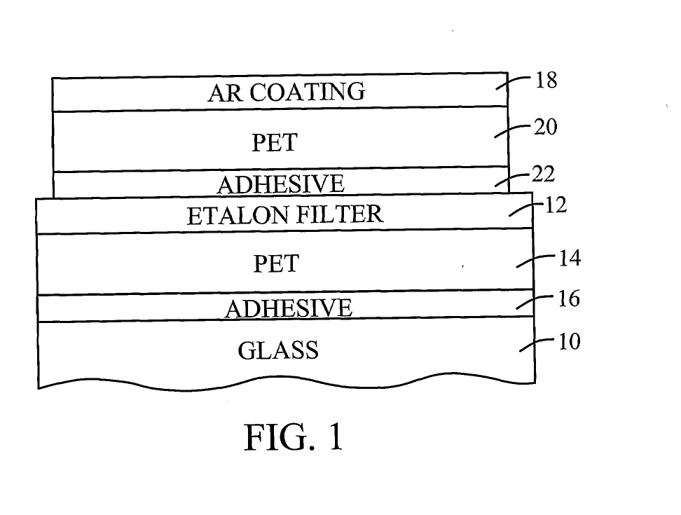

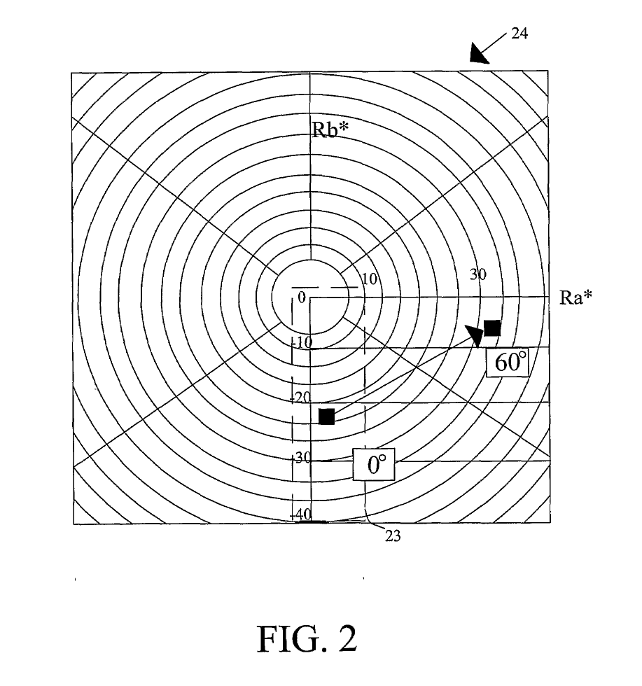

Between the color correcting layer 56 and the alternating pattern 26 is a hardcoat layer 58 that can be included in order to protect the underlying layers from scratches and contamination. Like the color correcting layer 56, the hardcoat layer is included in the preferred embodiment. However, the hardcoat layer is less important if the filter 100 is to be used with a top anti-reflection coating 18 on a second polymeric substrate 20, as shown in FIG. 1.

The total thickness of the metallic layers 36, 40, 44, 48 and 52 plays a significant role in achieving the desired optical properties. As previously noted, the total thickness should be greater than 50 nm. Optical properties for a filter having six indium oxide layers and five silver layers, where the total thickness for the silver layers was less than 50 nm, were computed. Specifically, the eleven layer thicknesses were 40 nm/10 nm/70 nm/10 nm/70 nm/10 nm/60 nm/6 nm/40 nm/6 nm/20 nm. This is consistent with Example 5 in U.S. Pat. No. 6,104,530 to Okamura et al. Transmission in the visible range of the spectrum (Tᵥᵢₛ), reflection in the visible range (Rᵥᵢₛ), and other optical properties were determined using an optical model calculation for this structure on PET, laminated with clear adhesive to glass and laminated with a commercial antireflective coating. The computed optical properties are shown in Table A. Generally, it is highly preferred that a plasma display have visible reflectance (Rᵥᵢₛ) of less than approximately five percent and that the reflected color at normal incidence (0 degrees) should be such that −Rb* is about 2 or more times larger than Ra*. Additionally, the color travel along the Ra* axis should be less than approximately 10 CIE units between viewing angles of 0 degrees and 60 degrees. From Table A, it can be seen that the filter has a large positive Rb* at 60 degrees, which would result in a brown or yellowish reflection appearance. In comparison, the filter 100 described with reference to FIG. 3 provides a negative or neutral Rb* at 60 degrees, corresponding to a neutral or bluish reflected color. Generally, the filter formed in accordance with the present invention has Rb* in the range of −10 to −20 at normal incidence, and Rb* of less than 2 at 60 degrees. Equally importantly, the sheet resistance may be less than 1.0 ohms/square.

TABLE A

| | Tᵥᵢₛ | Ta* | Tb* | Rᵥᵢₛ | Ra* | Rb* |
|---|---|---|---|---|---|---|
| 0° | 63% | −7.0 | 2.5 | 6.0% | 10.5 | 4.8 |
| 60° | 57.6% | −11.4 | −4.4 | 12.9% | 1.1 | 11.4 |

In another embodiment of the invention in which applications requiring sheet resistances lower than 0.5 ohms/square or less, a selected pattern of ultra-narrow conductive traces 64 may be printed onto the dielectric layer 54 prior to application of hardcoat 58. An inkjet printer may be used to apply a metallic ink containing highly conductive nano-particles, such as but not limited to copper, silver, gold or a combination of such materials. The ultra-narrow conductive traces 64 depicted in FIG. 4 preferably have a width of approximately 25 microns or less. The invention is not limited to the pattern shown. It is known in the art that alternative patterns may be used such as a pattern of non-parallel lines or a pattern that includes line intersections.

In another embodiment of the invention, the ultra-narrow conductive traces 64 may be printed onto the dielectric layer 54 utilizing a combination of photolithographic and electroplating techniques. Referring to FIG. 3, the alternating layers 32-54 would be dipped into a liquid precursor containing a nano-particle catalyst, such as palladium. Next, the coated substrate would be exposed to UV light in a preselected pattern. The pattern could be created via a scanning UV laser or a photo-mask. The areas exposed to the UV light will be activated to form the ultra-narrow conductive traces 64 when dipped in a solution containing metal ions that will grow in the selectively exposed areas. The entirety of the substrate may be immersed or only the surface of the substrate on which the traces are to be formed. The substrate may have the form of a roll (web) that has a region in contact with the solution. It is known to those of ordinary skill in the art that an inverse exposure step and then dipping step may be employed. That is, the areas that will not form the traces are exposed to the UV light. When dipped into the metal ion solution, the traces will grow in the unexposed areas to form the ultra-narrow conductive traces 64. A third embodiment of the invention is to print the ultra-narrow traces using offset, gravure, or similar type printing techniques in a continuous or semi-continuous mode.

As shown in FIG. 4, the ultra-narrow conductive traces 64 are electrically interconnected by at least one bus 66 and 68. In FIGS. 4 and 5, the conductive traces are on the same side of the overall device as the coating 26. For embodiments in which the conductive traces and the coating are on opposite sides of the substrate 28, one or both of the buses 66 and 68 may be electrically linked to the coating. The electrical linking can occur using techniques known in the art. In a simplistic approach, wires attach the buses to the coating 26.

The structure of FIG. 3 may be fabricated using indium oxide (or some other transparent conductive oxide) as the dielectric material and silver as the metallic material. A thin titanium layer (less than 2 nm thickness) may be deposited on top of each silver layer prior to deposition of the dielectric material, so as to improve the silver conductivity.

While the preferred embodiment is one in which the optical properties are formed by coating a substrate, embodiments are also contemplated in which the substrate itself is fabricated or treated to achieve the desired optical properties, such as a high infrared absorbence. Thus, the sputtering of layers is not critical to the invention. The substrate itself may be plain plastic, glass, IR-absorbing PET or PVB, an electrically conductive polymer, or optically coated substrates such as sputter coated glass and pyrolytically coated glass.

What is claimed is:

1. A method of providing an optical arrangement comprising:
providing a flexible transparent substrate; and
forming conductive micro traces on said substrate to achieve target electrical properties, said target electrical properties including at least one of providing target electromagnetic (EMI) shielding and providing an array of current-carrying elements, at least some of said conductive micro traces having a width of less than 25 microns, said width being measured parallel to a major surface of said substrate, said conductive micro traces being formed so as to maintain high visible light transmissivity of at least 70 percent through said optical arrangement.

2. The method of claim 1 wherein forming said conductive micro traces includes defining a pattern for said conductive micro traces on said coated substrate and then using electroplating techniques to form said conductive micro traces.

3. The method of claim 2 wherein defining said pattern includes applying a nano-particle catalyst to said substrate.

4. The method of claim 3 wherein defining said pattern further includes using selective light exposure to provide said pattern in said nano-particle catalyst.

5. The method of claim 2 wherein forming said conductive micro traces includes applying metallic ink.

6. The method of claim 1 wherein forming said conductive micro traces includes applying metallic ink as a seed layer.

7. The method of claim 6 wherein forming said conductive micro traces further includes using said seed layer in electroplating said conductive micro traces.

8. The method of claim 1 wherein forming said conductive micro traces includes defining said conductive micro traces as metallic ink.

9. The method of claim 8 wherein forming said conductive micro traces includes using inkjet printing techniques.

10. The method of claim 1 wherein forming said conductive micro traces includes using conventional printing techniques.

11. The method of claim 10 wherein using conventional printing techniques includes employing gravure printing.

12. The method of claim 1 wherein said conductive micro traces are organized and connected to provide heating elements.

13. The method of claim 1 further comprising forming a plurality of layers on said substrate to achieve target optical properties.

14. A method of providing an optical arrangement comprising:
forming a coated substrate to include an optical coating and an array of conductive micro traces, said optical coating being a sequence of layers that are cooperative to provide desired filtering properties, wherein forming said array of conductive micro traces includes:
utilizing a combination of photolithographic techniques and electroplating techniques to define and grow said array.

15. The method of claim 14 wherein utilizing said combination of photolithographic and electroplating techniques includes at least partially immersing said coated substrate in a solution having ions of a highly conductive material.

16. The method of claim 15 wherein said immersing is implemented upon a moving flexible web of said coated substrate.

17. The method of claim 14 wherein utilizing said combination of photolithographic and electroplating techniques includes forming said conductive micro traces to have widths of less than 25 microns.

18. The method of claim 14 wherein utilizing said combination of photolithographic and electroplating techniques includes forming material that is chemically altered when selectively exposed to light and then providing a selective exposure that defines said array to be formed by said electroplating.

19. The method of claim 14 further comprising affixing said coated substrate to a plasma display panel to provide optical filtering and EMI shielding.

20. The method of claim 14 further comprising affixing said coated substrate to a window of a vehicle to provide optical filtering and localized heating when said conductive micro traces are connected to a source of power.

21. The method of claim 14 further comprising affixing said coated substrate to a window of a residence or a business building.

22. The method of claim 14 further comprising affixing said coated substrate to a window of a refrigeration unit.

23. A method of providing an optical arrangement comprising:
forming a coated substrate to include an optical coating and an array of conductive micro traces, said optical coating being a sequence of layers that are cooperative to provide desired filtering properties, wherein forming said array of conductive micro traces includes:
utilizing inkjet printing techniques to deposit a metallic solution.

24. The method of claim 23 wherein utilizing inkjet printing techniques includes selectively directing metallic ink onto a moving web of flexible substrate material.

25. The method of claim 23 further comprising affixing said coated substrate to a plasma display panel to provide optical filtering and EMI shielding.

26. The method of claim 23 further comprising affixing said coated substrate to a window of a vehicle to provide optical filtering and localized heating when said conductive micro traces are connected to a source of power.

27. The method of claim 23 further comprising affixing said coated substrate to a window of a residence or a business building.

28. The method of claim 23 further comprising affixing said coated substrate to a window of a refrigeration unit.

29. The method of claim 23 wherein utilizing said inkjet printing techniques includes forming said conductive micro traces to have widths of less than 25 microns.
